(19) United States
(12) Patent Application Publication
(10) Pub. No.: US 2011/0265842 A1
(43) Pub. Date: Nov. 3, 2011

(54) METHOD FOR MOUNTING PHOTOVOLTAIC MODULES AND A PHOTOVOLTAIC ARRAY

(75) Inventors: Harald Bloess, Erfurt (DE); Marco Vogel, Erfurt (DE)

(73) Assignee: MASDAR PV GMBH, Ichtershausen (DE)

(21) Appl. No.: 13/094,924

(22) Filed: Apr. 27, 2011

(30) Foreign Application Priority Data
Apr. 28, 2010 (DE) 10 2010 018 837.9

(51) Int. Cl. H01L 31/042; B23P 11/00; H01L 31/18

(52) U.S. Cl. 136/244; 29/890.033; 29/462

(57) ABSTRACT

A method for mounting photovoltaic modules includes calculating a structural load of at least one photovoltaic module based on an expected mechanical load so as to determine optimal attachment locations on the at least one photovoltaic module for attachment elements. The attachment elements are disposed at the determined attachment locations so that the attachment elements extend partially over a section of the at least one photovoltaic module. The at least one photovoltaic module is attached to the substructure via the attachment elements.

### CROSS-REFERENCE TO PRIOR APPLICATIONS

Priority is claimed to German Patent Application No. DE 10 2010 018 837.9, filed on Apr. 28, 2010, the entire disclosure of which is hereby incorporated by reference herein.

### FIELD

The present invention relates to a method for mounting photovoltaic modules and to a photovoltaic array.

### BACKGROUND

European patent application EP 2 109 153 A2 describes a solar element for a photovoltaic array that has several attachment elements on its back that are attached by means of an adhesive bond to the base body of the solar element. The photovoltaic module that has been prefabricated in this manner is subsequently mounted onto a stationary substructure that is situated, for example, on a roof and that has a rail system with several holding rails. A drawback of such a photovoltaic array is that the modules can be damaged or break, especially in the case of photovoltaic modules with a large surface area and in the case of exposure to mechanical load due to the component stresses that occur.

### SUMMARY

In an embodiment, the present invention provides a method for mounting photovoltaic modules. A structural load of at least one photovoltaic module is calculated based on an expected mechanical load so as to determine optimal attachment locations on the at least one photovoltaic module for attachment elements. The attachment elements are disposed at the determined attachment locations so that the attachment elements extend partially over a section of the at least one photovoltaic module. The at least one photovoltaic module is attached to the substructure via the attachment elements.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 a top view of a mounted photovoltaic array in a first embodiment according to the invention,

FIG. 2 a side view of the photovoltaic array of FIG. 1,

FIG. 3 a top view of a mounted photovoltaic array in a second embodiment according to the invention, and

FIG. 4 a side view of the photovoltaic array of FIG. 3.

### DETAILED DESCRIPTION

An aspect of the present invention is to provide a method of mounting photovoltaic modules such that a high mechanical load-bearing capacity of the modules can be achieved with minimal effort in terms of production technology and with low manufacturing and assembly costs.

According to an embodiment, the present invention provides a method for mounting photovoltaic modules having at least one photovoltaic module that can be secured to a stationary substructure by means of attachment elements in that, first of all, a calculation of the structural load of the photovoltaic module is carried out under the mechanical load that can be expected during actual operation later on, in order to determine optimized attachment locations for the attachment elements, in that the attachment elements are then arranged at the attachment points that have been optimized as a function of the load, whereby the attachment elements extend partially over a section of the photovoltaic modules, and subsequently the photovoltaic modules are attached to the substructure by means of the attachment elements.

In comparison to the state of the art, it was recognized according to the present invention that the mechanical load-bearing capacity of the attachment of photovoltaic modules can be improved by calculating the structural load of the photovoltaic module under mechanical load and by optimizing the arrangement of the attachment elements to the attachment points that have been determined as a function of the load. The virtually punctual attachment of the photovoltaic modules at defined attachment points allows an improved distribution of the load-dependent deformation of the modules. The number and dimensions of the attachment elements are preferably determined as a function of the module size and module shape. In this manner, it is possible to securely affix modules that have particularly large surface areas, especially frameless modules, and that are configured as glass-glass photovoltaic modules having a surface area of more than 1 m².

According to an embodiment of the present invention, an overall high load-bearing capacity of the photovoltaic array is achieved with minimal material resources, so that the effort in terms of production technology is minimized and costs during the production, transport and assembly are reduced.

A load-dependent, punctual or sectional linear attachment of the photovoltaic modules is provided according to an embodiment of the present invention. The attachment points are preferably determined on the basis of computer-implemented strength models. The attachment that has been optimized according to an embodiment of the present invention allows a better distribution of the load-dependent deformation of frameless photovoltaic modules.

It has proven to be especially advantageous for the calculation of the structural load to be carried out by means of computer-implemented simulation, preferably by a finite element analysis (FEA) method and/or by a stress analysis. For example, the attachment points of the attachment elements are determined by means of computer-implemented strength models.

Damping elements, especially made of an elastomer, can be provided in the area of the attachment points in order to further improve the load application and in order to minimize stresses in the glass, especially in the edge area of the modules when they are under load.

The substructure can be configured as a rail system with several holding rails extending essentially parallel, in order to affix the photovoltaic modules. Such rail systems can be arranged, for example, on the roof and/or on a wall of a building or the like.

The photovoltaic modules preferably span several of the holding rails, whereby each holding rail has at least two attachment elements arranged at a distance from each other.

In a first embodiment, each photovoltaic modules spans three holding rails, whereby each holding rail has three attachment elements arranged at a distance from each other.

In such a variant, the attachment elements are arranged essentially in a circle, whereby each attachment element is positioned in an angular range of 0°, 45°, 90°, 135°, 180°, 225°, 270° and 315°, and whereby the 0° or 180° axis of the angular range extends approximately at an angle of 90° with respect to the longitudinal axis of the holding rails. This results in a homogeneous stress distribution in the photovoltaic module and an optimized force application into the substructure.

In this embodiment, it has proven to be very advantageous in terms of structural mechanics for the longitudinal axes of the attachment elements that are positioned in the angular range of 90° and in the angular range of 270° to extend approximately parallel, and for the longitudinal axes of the attachment elements that are positioned in the angular range of 0°, 45°, 135°, 180°, 225° and 315° to extend approximately perpendicular to the appertaining longitudinal axis of the holding rail. Moreover, it is preferable for at least one attachment element to be positioned in the area of the center of the circle. All in all, this allows a further optimized force flow.

According to an alternative embodiment of the present invention, each photovoltaic module spans four holding rails, whereby each holding rail has at least two attachment elements arranged at a distance from each other whose longitudinal axes preferably extend at an angle in the range of approximately 90° with respect to the longitudinal axis of the holding rails. In a preferred embodiment, all of the attachment elements are attached to the photovoltaic module in such a way that they each extend at an angle in the range of about 90° with respect to the longitudinal axis of the holding rail.

However, it can also be advantageous for the attachment elements to be simply arranged in parallel and orthogonally with respect to the holding rails, whereby the attachment elements can also extend over several holding rails.

According to an embodiment of the present invention, it is especially advantageous for the attachment elements to be attached to the back of the photovoltaic modules by means of an adhesive bond. In this manner, the attachment elements can be mounted easily and quickly onto the photovoltaic modules. Moreover, in terms of production technology, the attachment elements can be affixed easily, for example, automatically, onto the bottom of the photovoltaic modules during their manufacture. Drilled holes and other openings in the modules are not necessary in order to attach the attachment elements, which translates into a high strength of the modules.

The attachment elements are especially advantageously attached to the photovoltaic modules by means of silicon or an adhesive containing a silicon compound. Such adhesives have an elastic behavior with high strength so that no mechanical stresses between the substructure and the photovoltaic modules, or at least fewer, are transmitted, for example, due to different coefficient of thermal expansion.

As an alternative, the attachment elements can be attached to the photovoltaic modules by means of double-stick adhesive tape. In addition to being easy to apply, this also has the advantage that no curing times for the adhesive bond have to be taken into account.

Preferably, at least one of the attachment elements is arranged in an edge area of the photovoltaic module so that the modules are held especially securely as a result of the leverage ratios.

The photovoltaic module according to an embodiment of the present invention has at least one photovoltaic module that can be secured onto a stationary substructure by means of attachment elements. According to an embodiment of the present invention, the photovoltaic module has several partially arranged attachment elements for attaching the module to the substructure, which extend only over a partial section of the photovoltaic modules, whereby the attachment points of the attachment elements were determined as a function of the load.

In a preferred embodiment of the photovoltaic array, the attachment elements have an approximately omega-shaped profile cross section, whereby a middle section of the attachment elements is joined to the substructure and free profile legs are attached to the photovoltaic module. Any other profile cross section with which the photovoltaic module can be joined to the substructure is likewise possible.

In order to further reduce the mechanical stresses between the attachment elements and the substructure, for example, due to different coefficients of thermal expansion on the part of the modules and of the substructure, damping elements are preferably arranged between the attachment elements and the substructure. In particular, an elastomer can be provided as the damping element.

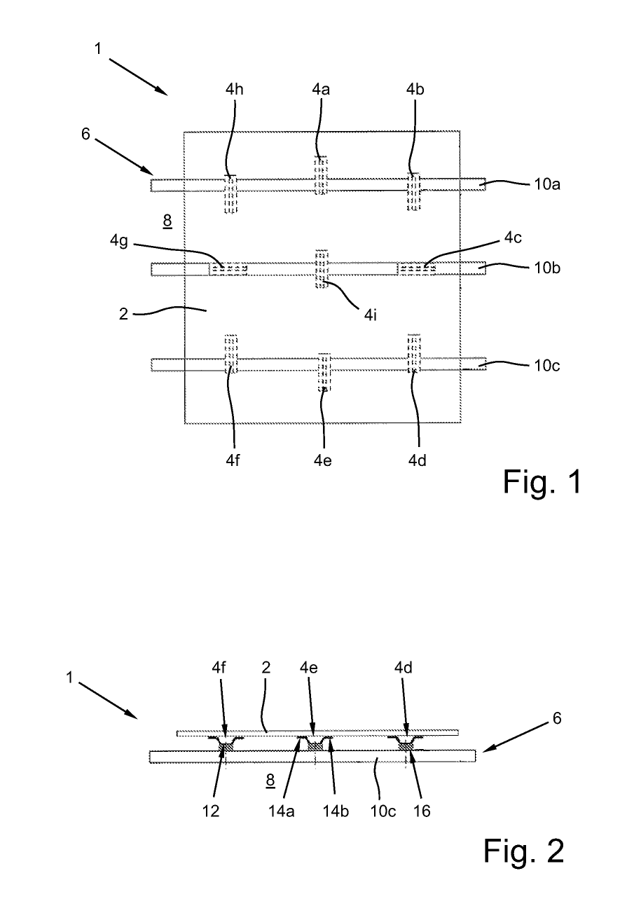

FIG. 1 shows a photovoltaic array 1 according to an embodiment of the present invention with a flat arrangement of the photovoltaic module 2 that is attached by means of several attachment elements 4a-4i provided on a stationary substructure 6. The photovoltaic module 2, shown by way of an example, is configured as a glass-glass laminate and, in the embodiment shown, is attached by means of the substructure 6 onto a building roof 8.

According to an embodiment of the present invention, before the photovoltaic module 2 is mounted, a calculation of the structural load of the module under the assumed mechanical load later on is carried out in order to determine optimized attachment points for the attachment elements 4a-4i. The calculation of the structural load was carried out by means of a computer-implemented finite element analysis. In this context, a determination of the attachment points on the basis of computer-implemented strength models has proven to be especially advantageous. The attachment elements 4a-4i were subsequently arranged at the attachment points that had been optimized as a function of the load, whereby the attachment elements 4a-4i extend partially over a section of the photovoltaic modules 2. The attachment elements 4a-4i each preferably extend over a length encompassing approximately 10% to 20% of the length of the module.

Subsequently, the photovoltaic modules 2 were attached to the substructure 6 by means of the attachment elements 4a-4i. Because the calculated arrangement of the attachment elements 4a-4i to the attachment points had been optimized as a function of the load, a high mechanical strength of the attachment is ensured, even in case of a high mechanical load. As a result, it is possible to securely affix modules that have particularly large surface areas, especially frameless modules, and that are configured as glass-glass photovoltaic modules having a surface area of more than 1 m². The depicted module 2, for example, has a surface area of approximately 5.72 m².

The substructure 6 is configured as a rail system with several holding rails 10a-10c extending parallel to each other in order to affix the photovoltaic modules 2. In the embodiment shown, the photovoltaic modules 2 each span three holding rails 10a-10c, whereby each holding rail 10a-10 has three attachment elements arranged at a distance from each other. The attachment elements 4a-4h are arranged essentially in a circle, whereby in each case, an attachment element 4a-4h is positioned in an angular range of 0°, 45°, 90°, 135°, 180°, 225°, 270° and 315°, and whereby the 0° or 180° axis of the angular range extends approximately at an angle of 90° with respect to the longitudinal axis of the holding rails. Here, it has proven to be very advantageous in terms of structural mechanics for the longitudinal axes of the attachment elements 4c, 4g that are positioned in the angular range of 90° and in the angular range of 270° to extend approximately parallel, and for the longitudinal axes of the attachment elements 4a, 4b, 4d, 4e, 4f, 4h that are positioned in the angular range of 0°, 45°, 135°, 180°, 225° and 315° to extend approximately perpendicular to the appertaining longitudinal axis of the holding rails and to only be joined to the holding rail 10a, 10c in an edge area. The attachment element 4i is arranged in the area of the center of the circle in the middle of the middle holding rail 10b.

As can be seen in FIG. 2, which shows a side view of the photovoltaic array 1 from FIG. 1, the attachment elements 4a-4i have an approximately omega-shaped profile cross section, whereby a middle section 12 of the attachment elements 4a-4i is joined to the substructure 6, and free profile legs 14a, 14b are attached to the photovoltaic module 2. An elastomer damping element 16 with an approximately rectangular cross section is arranged between each of the attachment elements 4a-4i and the substructure 6. Here, the joining surface of the damping element 16 corresponds to the surface of the middle section 12 of the attachment elements 4a-4i. The attachment elements 4a-4i are attached to the back of the photovoltaic modules 2 by means of a silicon-based adhesive, so that no mechanical stresses, or at least fewer, occur. Drilled holes and other openings are not necessary in order to attach the modules 2, so that overall, a high strength is achieved. In other embodiments, the omega-shaped profile cross section can have any other shape with outer surfaces that are configured in parallel opposite from each other.

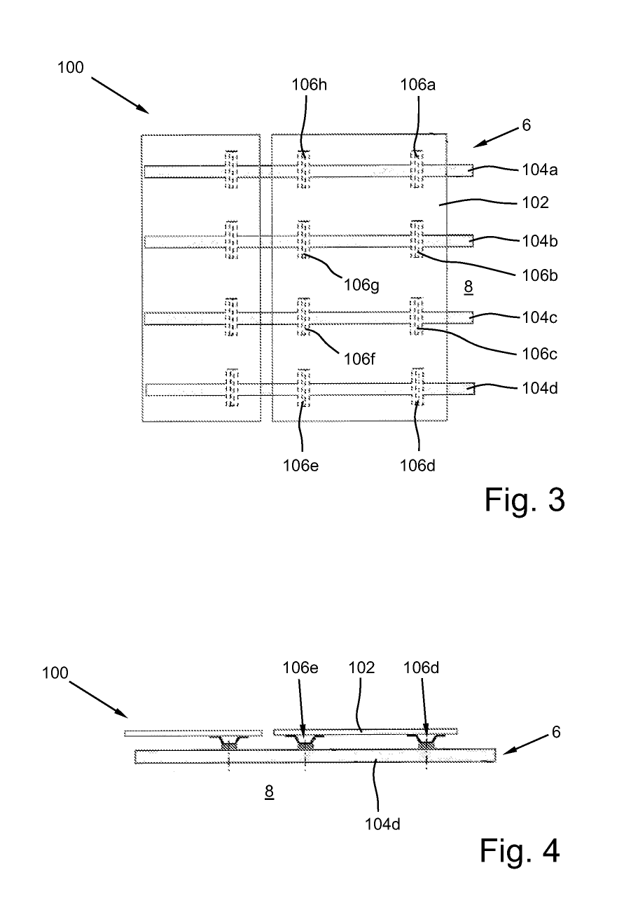

FIG. 3 shows a photovoltaic array 100 according to a second embodiment of the present invention that differs from the above-mentioned embodiment essentially by a simplified arrangement of the attachment elements. According to FIG. 3, the photovoltaic modules 102 here each span four holding rails 104a-104d, whereby each holding rail 104a-104d has two attachment elements 106a-106h arranged at a distance from each other in edge areas of the modules 102. The attachment elements 106a-106d and the attachment elements 106e-106h are each arranged in a row with a shared longitudinal axis. The longitudinal axes of the attachment elements 106a-106h extend at an angle of approximately 90° with respect to the longitudinal axis of the holding rails 104a-104d. The photovoltaic module 102 that is shown by way of an example and that is secured in a manner optimized according to the invention has a surface area of approximately 2.86 m².

As can be seen in FIG. 4, which shows a side view of the photovoltaic array 100 of FIG. 3, the attachment elements 106a-106h are configured as already explained for FIG. 2, so that reference is hereby made to this part of the description.

According to embodiments of the present invention, a high load-bearing capacity of the photovoltaic array 1, 100 is achieved overall with minimal material resources, so that the effort in terms of production technology is minimized and costs are reduced during the production, transport and assembly.

According to an embodiment, the present invention provides a method for mounting photovoltaic modules 2, 102 having at least one photovoltaic module 2, 102 that can be secured to a stationary substructure 6 by means of attachment elements 4, 106, comprising the steps:

a) calculation of the structural load of the photovoltaic module 2, 102 under a mechanical load that can be expected, in order to determine optimized attachment points for the attachment elements 4, 106,

b) arrangement of the attachment elements 4, 106 at the attachment points that have been optimized as a function of the load, whereby the attachment elements 4, 106 extend partially over a section of the photovoltaic modules 2, 102, and

c) attachment of the photovoltaic modules 2, 102 to the substructure 6 by means of the attachment elements.

Moreover, according to an embodiment, the present invention provides a photovoltaic array with several partially arranged attachment elements 4, 106, whereby the attachment points of the attachment elements 4, 106 were determined as a function of the load.

While the invention has been described with reference to particular embodiments thereof, it will be understood by those having ordinary skill the art that various changes may be made therein without departing from the scope and spirit of the invention. Further, the present invention is not limited to the embodiments described herein; reference should be had to the appended claims.

### LIST OF REFERENCE NUMERALS

1 photovoltaic array

2 photovoltaic module

4a-4i attachment element

6 substructure

8 building roof

10a-10c holding rail

12 middle section

14a-14b profile leg

16 damping element

100 photovoltaic array

102 photovoltaic module

104a-104d holding rail

106a-106h attachment element

What is claimed is:

1. A method for mounting photovoltaic modules, comprising the steps:
calculating a structural load of at least one photovoltaic module based on an expected mechanical load so as to determine optimal attachment locations on the at least one photovoltaic module for attachment elements;
disposing the attachment elements at the determined attachment locations so that the attachment elements extend partially over a section of the at least one photovoltaic module, and
attaching the at least one photovoltaic module to the substructure via the attachment elements.

2. The method according to claim 1, wherein the calculating of the structural load includes performing a finite element analysis method under the expected mechanical load.

3. The method according to claim 1, wherein the attaching of the at least one photovoltaic module to the substructure includes connecting the attachment elements to a rail system of the substructure having a plurality of holding rails that extend substantially in parallel to one another.

4. The method according to claim 3, wherein the attaching of the at least one photovoltaic module to the substructure includes disposing each of the at least one photovoltaic module so as to span at least two of the plurality of holding rails and connecting at least two of the attachment elements at a distance from one another to each of the at least two of the plurality of holding rails.

5. The method according to claim 3, wherein the attaching of the at least one photovoltaic module to the substructure includes disposing each of the at least one photovoltaic module so as to span four of the plurality of holding rails and connecting at least two of the attachment elements at a distance from one another to each of the four of the plurality of holding rails so that longitudinal axes of the at least two attachment elements extend substantially at an angle of 90° with respect to a longitudinal axis of the four of the plurality of holding rails.

6. The method according to claim 3, wherein the connecting of the attachment elements includes disposing the attachment elements substantially in a circle such that the attachment elements are respectively disposed in an angular range at 0°, 45°, 90°, 135°, 180°, 225°, 270° and 315°, and at least one of a 0° and 180° axis of the angular range extends approximately at an angle of 90° with respect to a longitudinal axis of the plurality of holding rails.

7. The method according to claim 6, wherein the connecting of the attachment elements includes arranging longitudinal axes of the attachment elements positioned in the angular range at 90° and 270° substantially parallel to one another, and arranging longitudinal axes of the attachment elements positioned in the angular range at 0°, 45°, 135°, 180°, 225° and 315° substantially perpendicular to the longitudinal axis of the plurality of holding rails.

8. A photovoltaic array, comprising:
at least one photovoltaic module; and
a plurality of attachment elements configured to attach the at least one photovoltaic module, at attachment locations, to a stationary substructure with the attachment elements extending partially over a section of the at least one photovoltaic module, including attachment locations corresponding to an expected mechanical load on the at least one photovoltaic module.

9. The photovoltaic array according to claim 8, wherein the attachment elements have a substantially omega-shaped profile cross section including a middle section configured to be joined to the substructure and free profile legs configured to attach to the at least one photovoltaic module at the attachment locations.

10. The photovoltaic array according to claim 8, further comprising at least one damping element disposed between the attachment elements and the substructure.

11. The photovoltaic array according to claim 10, wherein the damping element includes an elastomer.
